(19) United States
(12) Patent Application Publication
(10) Pub. No.: US 2003/0175426 A1
(43) Pub. Date: Sep. 18, 2003

(54) Heat treatment apparatus and method for processing substrates

(75) Inventor: Wakako Shiratori, Tokyo (JP)

Correspondence Address: BACON & THOMAS, PLLC, 625 SLATERS LANE, FOURTH FLOOR, ALEXANDRIA, VA, 22314

(73) Assignee: HITACHI KOKUSAI ELECTRIC INC., Tokyo (JP)

(21) Appl. No.: 10/383,636

(22) Filed: Mar. 10, 2003

(30) Foreign Application Priority Data
Mar. 14, 2002 (JP) 2002-070065

(51) Int. Cl. C23C 16/00; C23C 16/40

(52) U.S. Cl. 427/255.37; 118/724; 118/715; 427/255.18; 427/255.23; 427/255.28; 427/255.29

(57) ABSTRACT

In a method for processing a substrate, a plurality of substrates maintained in a boat are loaded into a cylindrical inner tube disposed in a cylindrical outer tube. A processing gas is supplied into a process room, and thereafter the substrates are batch-processed with the processing gas evacuated through an exhaust path formed between the inner tube and the outer tube, wherein nitrogen gas is supplied to a surface region of the ceiling of the outer tube during a film forming process of the substrates, thereby the processing gas ascended through the process room is prevented from coming into contact with the ceiling of the outer tube by the nitrogen gas covering thereat. Accordingly, products and/or by-products of the film forming gas is prevented from being adhered thereto, thereby formation of contaminants due to the deterioration of the deposition of the products and the by-products thereof can be eliminated/reduced.

### FIELD OF THE INVENTION

The present invention relates to a substrate processing method and apparatus; and, more particularly, to a substrate processing method and apparatus capable of manufacturing semiconductor integrated circuits (ICs) by providing a processing gas in a reaction chamber to deposit a silicon oxide layer, a polycrystalline silicon layer or a silicon nitride layer on a substrate, e.g., semiconductor wafer (hereinafter referred to as wafer).

### BACKGROUND OF THE INVENTION

In a method for fabricating ICs, a vertical batch type hot-wall low pressure CVD apparatus has been widely used in forming a CVD film, e.g., a silicon oxide layer, a polycrystalline silicon layer or a silicon nitride layer, on a wafer. Such a vertical batch type hot-wall low pressure CVD apparatus (hereinafter referred to as a CVD apparatus) includes a vertically disposed bell jar type process tube provided with an inner tube, into which wafers are loaded, and an outer tube surrounding the inner tube, the process tube constituting a reaction chamber; a gas supply line for supplying a film forming gas into the reaction chamber; an exhaust line for vacuum-evacuating the inside of the reaction chamber; and a heater unit, for heating the reaction chamber, installed outside the process tube. A plurality of horizontally disposed wafers that are vertically stacked in a boat are loaded into the reaction chamber through a furnace mouth formed at the bottom thereof, and then the film forming gas is provided from the gas supply line into the reaction chamber, while the reaction chamber is heated by the heater unit, thereby forming a CVD film on each of the wafers.

As well known, TEOS(tetraethylorthosilicate)-O₃ is widely used in a CVD apparatus for growing a SiO₂ film rather than SiH₄—O₂ since TEOS has a high deposition rate of about 150 nm per min at a substrate temperature of 350° C. and is well incorporated into grooves formed on the substrate.

It has been found by the present inventors that if a film forming process is repeated using a TEOS gas in the aforementioned CVD apparatus, a TEOS film is gradually deposited on an inner surface of the ceiling of the outer tube and then is eventually deteriorated in a form of debris when the film reaches a certain thickness, resulting in particulate contaminants in the reaction chamber.

### SUMMARY OF THE INVENTION

It is, therefore, an object of the present invention to provide a substrate processing method and apparatus capable of preventing a product and/or a by-product of a processing gas from being adhered to an inner surface of the ceiling or top wall of an outer tube.

In accordance with one aspect of the present invention, there is provided a method for fabricating semiconductor devices, including the steps of: loading a plurality of substrates maintained in a boat into an inner tube, the inner tube being of a cylindrical shape having open upper and lower ends, and being disposed in an outer tube, the outer tube being of a cylindrical shape having a closed upper end and an open lower end; supplying a processing gas into the inner tube to process the substrates; and evacuating the processing gas through an exhaust path formed between the inner tube and the outer tube, wherein a non-reactive gas is provided to an inner surface of the closed upper end of the outer tube during the step of supplying the processing gas.

In accordance with another aspect of the present invention, there is provided a method for fabricating semiconductor devices, comprising the steps of: loading a plurality of substrates maintained in a boat into an inner tube, the inner tube being of a cylindrical shape having open upper and lower ends, and being disposed in an outer tube, the outer tube being of a cylindrical shape having a closed upper end and an open lower end; supplying a processing gas into the inner tube to form a film on each of the substrates while the substrates are heated, wherein a non-reactive gas is provided to an inner surface of the closed upper end of the outer tube during the film forming process of the substrates; and evacuating the processing gas through an exhaust path formed between the inner tube and the outer tube.

In accordance with another aspect of the present invention, there is provided a semiconductor fabricating apparatus including: an outer tube; an inner tube disposed inside the outer tube, forming a substrate processing region; a boat loaded into the substrate processing region while hosting a plurality of vertically stacked substrates; a heater surrounding the outer tube for heating the substrates; a gas supply line for providing a reaction gas from a bottom part of the inner tube; and a non-reactive gas outlet provided in a part of the outer tube above the inner tube.

In accordance with still another aspect of the present invention, there is provide a semiconductor fabricating apparatus including: an outer tube; an inner tube disposed inside the outer tube, forming a substrate processing region; a boat loaded into the substrate processing region while hosting a plurality of vertically stacked substrates; a heater surrounding the outer tube for heating the substrates; a gas supply line for providing a reaction gas from a bottom part of the inner tube; and a non-reactive gas outlet facing toward an inner part of the outer tube above the inner tube.

### BRIEF DESCRIPTION OF THE DRAWINGS

The above and other objects and features of the present invention will become apparent from the following description of preferred embodiments given in conjunction with the accompanying drawings, in which:

FIG. 1 shows a frontal cross sectional view of a CVD apparatus in accordance with a first preferred embodiment of the present invention;

FIG. 2 describes a frontal cross sectional view of a CVD apparatus in accordance with a second preferred embodiment of the present invention; and

FIG. 3 illustrates a frontal cross sectional view of a CVD apparatus in accordance with a third preferred embodiment of the present invention.

### DETAILED DESCRIPTION OF THE PREFERRED EMBODIMENTS

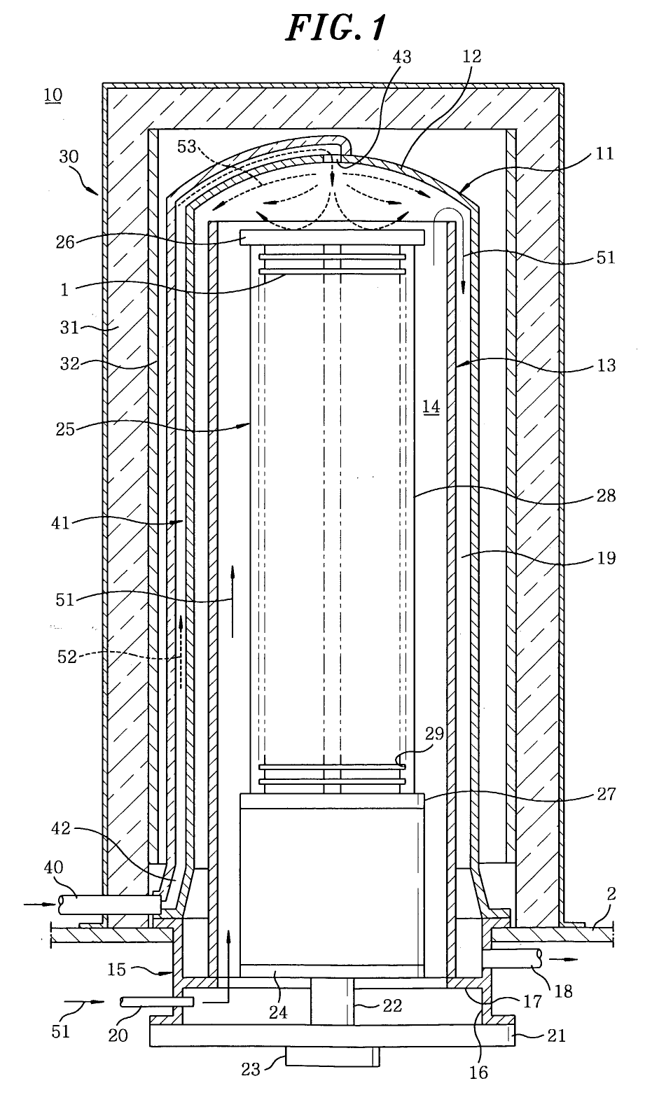

A first preferred embodiment of the present invention will now be described with reference to the accompanying drawing of FIG. 1.

In accordance with the first preferred embodiment of the invention, a substrate processing method is carried out by using a CVD apparatus 10 shown in FIG. 1. The CVD apparatus 10 includes a vertically displaced bell jar type process tube 11, which is fixedly supported so that its longitudinal centerline is vertical. The process tube 11 is formed of an outer tube 12 and an inner tube 13 disposed in the outer tube 12. The outer and the inner tubes 12, 13 are concentrically arranged. The outer tube 12, preferably made of quartz glass and generally having a cylindrical shape, is seamlessly formed with its upper end closed and its lower end open.

The inner tube 13, preferably made of quartz glass or silicon carbide, generally also has a cylindrical shape with its upper and lower ends open. A cylindrical hollow portion of the inner tube 12 forms a reaction chamber 14 in which a plurality of wafers 1 concentrically arranged in a boat are loaded. Such being the case, an inner diameter of the inner tube 13 is set to be greater than an outer diameter of the to-be-processed wafers 1.

As shown in FIG. 1, a manifold 15 is provided directly under the process tube 11 to support same. The manifold 15 has a short cylindrical shape with both of its upper and lower ends open, and is concentrically arranged with a lower end portion of the inner tube 13. The lower end opening portion of the manifold 15 serves as a furnace mouth 16 of the reaction chamber 14. The manifold 15 is supported by a partially depicted housing 2, so that the process tube 11 is to be vertically disposed thereon. Horizontally arranged at a middle portion of an inner circumference of the manifold 15 is a partition wall 17 which divides an inner space of the manifold 15 into an upper and a lower portion. The inner tube 13 is supported by the partition wall 17 and the inner diameter of the inner tube 13 is substantially the same as that of the partition wall 17. The outer tube 12 is supported by a top end of the manifold 15.

Provided at a side wall of the manifold 15 is an exhaust line 18 having two ends; one end being connected to the upper portion of the manifold 15 and the other end being connected to a vacuum exhaust device (not shown). The exhaust line 18 communicates with an exhaust path 19, i.e., a space between the inner tube 13 and the outer tube 12. Connected to the lower portion of the manifold 15 where the furnace mouth 16 resides is one of the two ends of a gas supply line 20. The other end of the supply line 20 is connected to a material gas or nitrogen gas supply device (not shown).

The CVD apparatus 10 is provided with a sealing cap 21 functioning as an isolation valve for opening and closing the furnace mouth 16 of the manifold 15. The sealing cap 21 and the manifold 15 are concentrically arranged such that the center lines of the former and the latter coincide with each other. The sealing cap 21 is configured to be ascended and descended by a boat elevator (not shown).

Vertically coupled at the center of the sealing cap 21 is a rotary rod 22, which is rotatably supported by a bearing device and rotatably driven by a rotary actuator 23 installed under the sealing cap 21. Horizontally fixed on an upper end of the rotary rod 22 is a supporting plate 24, on which a boat 25 is vertically fixed.

As shown in FIG. 1, the boat 25 is provided with a pair of top and bottom plates 26 and 27 and a plurality of supporting bars 28 vertically arranged therebetween. A multiplicity of horizontally formed supporting grooves 29 are vertically arranged in the supporting bars 28 with a predetermined interval therebetween so as to be opened in multiple horizontal planes. Further, outer circumferential portions of the wafers 1 is inserted into the supporting grooves 29, so that the wafers 1 are horizontally maintained in the boat 25 with their centers being vertically aligned. The top plate 26 functions as a blind patch so as to reflect the flow of a nitrogen gas provided from a top portion of the reaction chamber 14 as will be described later in detail.

Further, concentrically installed outside the reaction chamber 11 is a heater unit 30 for heating the reaction chamber 11 to have a uniform or predetermined temperature distribution therein. The heater unit 30 is vertically supported by the housing 2. Specifically, the heater unit 30 is provided with a cylindrical heat insulating cover 31 and one or more resistive heaters 32. The cover 31 has an inner diameter greater than the outer diameter of the outer tube 12 and also has a closed upper end and an open lower end. The resistive heaters 32 are helically installed at an inner surface of the heat insulating cover 31. The heat insulating cover 31 covers the outer tube 12, and is installed on the housing 2.

As shown in FIG. 1, installed along a part of the outer surface of the outer tube 12 is a nitrogen gas conduit 41 for introducing nitrogen gas into an upper portion of the outer tube 12. An inlet 42 of the nitrogen gas conduit 41 is arranged at a bottom portion of the outer tube 12, wherein the inlet 42 is connected to a nitrogen gas supply line 40 connected to a nitrogen gas supply source (not shown). A top end portion of the nitrogen gas conduit 41 forms an outlet 43 installed at a center portion of the ceiling of the outer tube 12. The outlet 43 is designed to slowly inject the nitrogen gas into proximity of the ceiling of the outer tube 12.

A TEOS film forming process on wafers by using the CVD apparatus 10 in accordance with the first embodiment will now be described.

First, a plurality of wafers 1 which are horizontally held in the boat 25 are maintained in a boat loading/unloading chamber (not shown) constructed in a housing 2 below the reaction chamber 11. As shown in FIG. 1, the boat 25 having the horizontally placed wafers 1 therein is loaded in a way that the wafers 1 are vertically stacked and maintained above the sealing cap 21. Specifically, it is loaded into the reaction chamber 11 through the furnace mouth 16 of the manifold 15 by an ascending motion of the boat elevator, and disposed in the reaction chamber 11 while being supported by the sealing cap 21, wherein the furnace mouth 16 is sealed by the sealing cap 21.

The inner space of the process tube 11 is vacuum-evacuated to a predetermined vacuum pressure (several tens to several tens of thousands of Pa) through the exhaust line 18. Further, the entire inner space of the reaction chamber 11 is uniformly heated to a predetermined temperature (of about 600° C.) by the heater unit 30.

Subsequently, upon stabilization of the interior temperature and pressure of the process tube 11 a film forming gas 51 is supplied into the reaction chamber 14 inside the inner tube 13 through the gas supply line 20. In particular, in the first embodiment, TEOS and O₃ gases are used as the film forming gas.

The supplied film forming gas 51 is ascended along the reaction chamber 14 of the inner tube 13, passing through the opening at the top thereof, and is then flowed through an exhaust path 19 formed between the inner tube 13 and the outer tube 12, thereby enabling evacuation through the exhaust line 18. Such film forming gas 51 comes into contact with surfaces of the wafers 1 when passing through the reaction chamber 14. TEOS films are deposited on surfaces of the wafers 1 by a CVD reaction of the film forming gas 51 in contact with the wafers 1.

In the first embodiment of the present invention, in order to suppress adherence of the products and/or the by-products of the film forming gas 51 on the surface of the ceiling of the outer tube 12, a non-reactive gas, e.g., nitrogen gas 52, is slowly and continuously injected from the outlet 43 of the nitrogen gas conduit 41, while the film forming gas 51 is supplied. A part of the supplied nitrogen gas 52 injected from the outlet 43 into the process tube 11, is radially diffused along the surface of the ceiling of the outer tube 12 by the suction force of the exhaust line 18 exerted through the exhaust path 19 formed between the outer tube 12 and the inner tube 13; and the remaining supplied gas flows downward to collide into the top plate 26 of the boat 25 and is then reflected toward the exhaust path 19 to be eventually evacuated therethrough. Accordingly, formed at a region below the ceiling of the outer tube 12 is a nitrogen gas atmosphere 53. Thus, due to the nitrogen gas atmosphere 53 formed thereat, the film forming gas 51 ascended from the lower portion of the reaction chamber 14 is prevented from coming into contact with the surface of the ceiling of the outer tube 12. Accordingly, the formation of the product and/or by-product of the TEOS gas otherwise adhered thereto can be prevented. In general, if the film forming gas 51 has molecular weight as great as TEOS gas, the occurrence of mixture between the nitrogen gas 52 and the film forming gas 51 can be suppressed thereby and therefore the nitrogen gas atmosphere 53 can effectively be formed on the surface of the ceiling of the outer tube 12.

After a predetermined processing time for depositing the TEOS film having a desired film thickness has elapsed, the sealing cap 21 is lowered to open the furnace mouth 16, enabling the group of wafers 1 held in the boat 25 to be unloaded therethrough and to be placed in the boat loading/unloading chamber disposed below the reaction chamber 11.

In the above-described film forming process, in the absence of the nitrogen gas 52 atmosphere near the ceiling of the outer tube 12, the film forming gas 51 ascends through the top opening portion of the inner tube 13 and comes into contact with the surface of the ceiling of the outer tube 12, thereby yielding the products and/or the by-products of the TEOS gas, which adhere thereto. The accumulation of the products and/or the by-products of the TEOS gas adhered thereto grow over time as the film forming process is repeated, and thus the thickness of the deposited film is increased as the number of the film forming batch process increases. As the accumulation of the deposited film reaches certain thickness, it readily deteriorates in a form of a block, resulting in the generation of the foreign material.

In the CVD apparatus 10 in accordance with the first embodiment, however, the nitrogen gas 52 is injected from the outlet 43 of the nitrogen gas conduit 41 during the aforementioned film forming process, which forms nitrogen gas atmosphere 53 at the surface region of the ceiling of the outer tube 12, thereby preventing the film forming gas 51 from coming into contact with the surface of the ceiling of the outer tube 12. Therefore, the adhesion of the products and/or the by-products of the TEOS gas thereto are eliminated. Accordingly, by preventing the products and/or the by-products of the TEOS gas from being deposited on the surface of the ceiling of the outer tube 12, generation of the foreign materials precipitated by the deterioration of the products and/or the by-products of the TEOS gas deposited thereon can be prevented. Therefore, maintenance or repair of the CVD apparatus to avoid the generation of the foreign materials can be eliminated or reduced.

Following effects can be achieved by the preferred embodiment of the present invention.

1) The nitrogen gas is injected from the outlet of the nitrogen gas conduit installed at the ceiling of the outer tube during the film forming process, which forms the nitrogen gas atmosphere near the surface of the ceiling of the outer tube, thereby preventing the film forming gas from coming into contact with the surface of the ceiling of the outer tube. Therefore, the products and/or the by-products generated by the film forming gas can be prevented from adhering to the surface of the ceiling of the outer tube.

2) By preventing the film forming gas from coming into contact with the inner surface of the ceiling of the outer tube, deposition of the products and/or the by-products of the film forming gas can be prevented so that the foreign materials or impurities generated by the deterioration of the deposited film can be prevented. Thus, the yield and throughput of the CVD apparatus, and the CVD process and the IC manufacturing process in general, can be increased.

3) By preventing the deposition of the products and the by-products, maintenance or repair due to the generation of the foreign materials or impurities can be eliminated or reduced, so that the operating efficiency of the CVD apparatus, and the CVD process and overall IC manufacturing process can be increased.

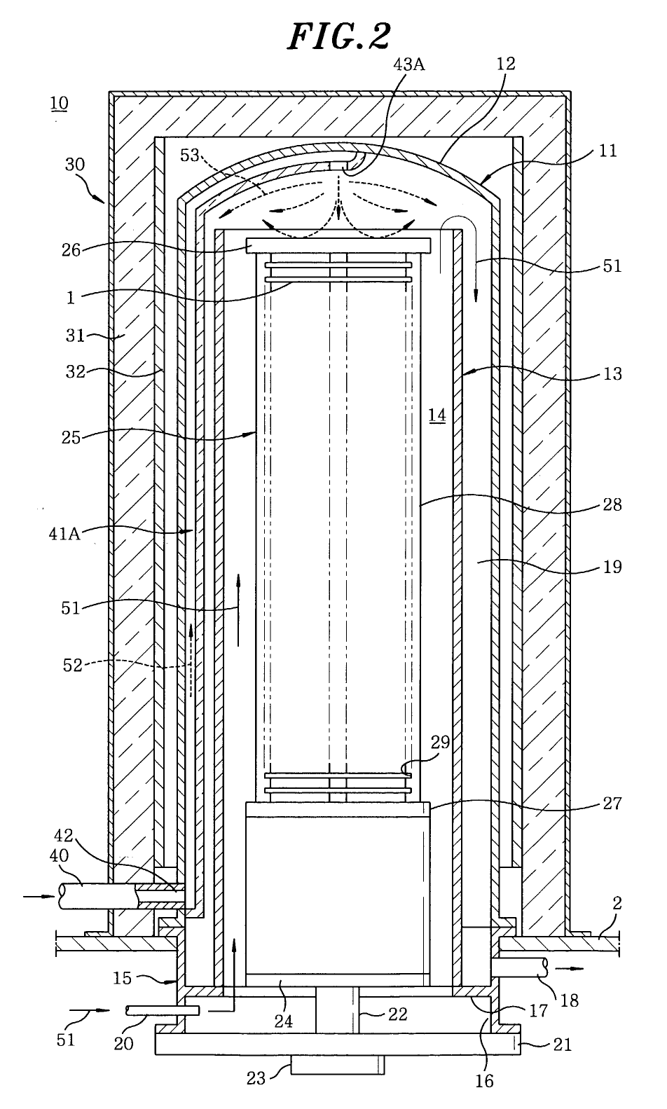

Referring to FIG. 2, there is described a frontal cross sectional view of a CVD apparatus in accordance with a second preferred embodiment of the present invention.

The second embodiment is different from the first embodiment in that a nitrogen gas conduit 41A is installed along an inner surface of the wall of the outer tube 12 and the nitrogen gas outlet 43A is projected downward in the center portion of the ceiling of the outer tube 12.

Also in the present embodiment, the nitrogen gas 52 is injected from the outlet 43A of the nitrogen gas conduit 41A, so that the nitrogen gas atmosphere 53 is provided in the lower region of the ceiling of the outer tube 12, covering the surface of the ceiling of the outer tube 12. Hence generation of the products and/or the by-products of the film forming gas 51, which would have been otherwise adhered to the surface of the ceiling of the outer tube 12, can be prevented. Therefore, maintenance or repair due to the foreign materials or impurities generated by the deterioration of the deposited products and/or by-products of the film forming gas 51 on the ceiling can be eliminated or reduced.

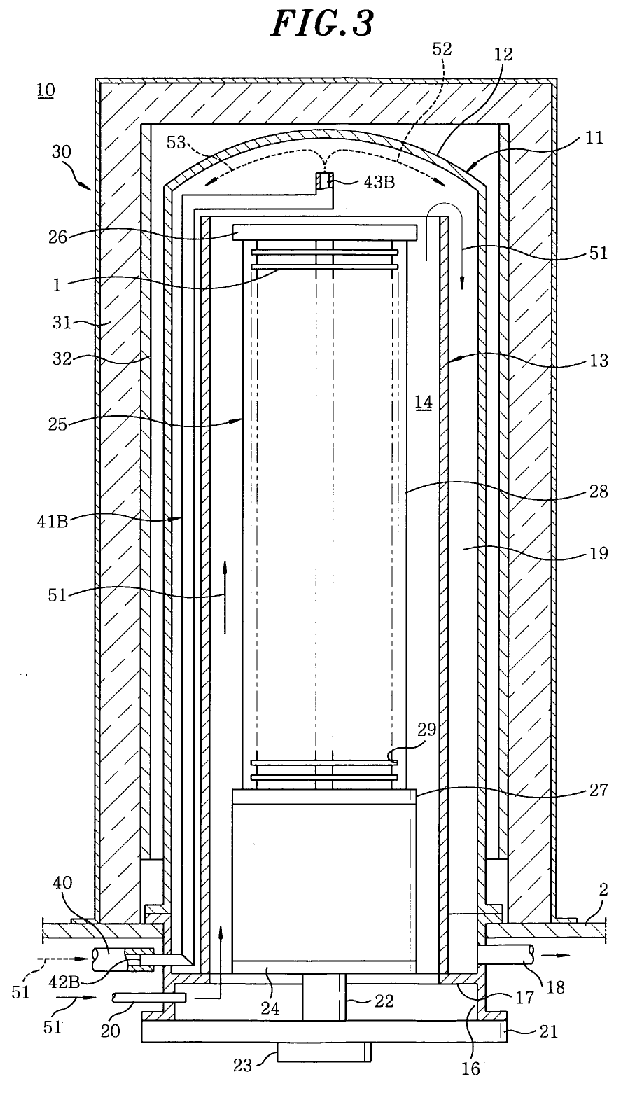

Referring to FIG. 3, there is describes a frontal cross sectional view of a CVD apparatus using a CVD method in accordance with a third preferred embodiment of the present invention.

The third embodiment is different from the other embodiments in that a nitrogen gas conduit 41B is installed between the outer tube 12 and the inner tube, and an inlet 42B is arranged at the manifold 15 and an outlet 43B of the nitrogen gas conduit 41B is projected upward so that the nitrogen gas 52 is injected to the center portion of the ceiling of the outer tube 12.

In the present embodiment, the nitrogen gas 52 is injected to the center portion of the ceiling of the outer tube 12, so that the nitrogen gas atmosphere 53 is formed thereat, covering the surface of the ceiling of the outer tube 12, and thus preventing the products and/or the by-products of the film forming gas 51 from being adhered to the surface of the ceiling of the outer tube 12. Therefore, maintenance or repair due to the impurities generated by the deterioration of the deposited products and/or the by-products of the film forming gas on the ceiling can be eliminated or reduced.

The present invention is not intended to be limited by the specific embodiments described above, but should be construed that the preferred embodiments described above can be modified without departing from the scope of the invention.

For example, the non-reactive gas is not limited to the nitrogen gas, but rather can be an inert gas, e.g., helium gas, argon gas or the like. The outlet of such gas may be constructed in a form of a showerhead. Moreover, the present invention is not limited to the formation of a TEOS film, but may be applicable in the field of fabricating a polycrystalline silicon film, a silicon oxide film or the like.

In addition, the present invention is also applicable to other types of CVD apparatus, such as a horizontal hot-wall type low pressure CVD apparatus, as well as a vertical batch type hot-wall low pressure CVD apparatus.

The present invention is also applicable to oxidation and diffusion processes as well as a carrier activation process after ion implantation or a reflow process for planarization.

It should be noted that the present invention can be employed in processing other substrates, e.g., photo masks, printed circuit boards, liquid crystal panels, compact disks and magnetic disks, other than wafers set forth in the preferred embodiments.

While the invention has been shown and described with respect to the preferred embodiments, it will be understood by those skilled in the art that various changes and modifications may be made without departing from the spirit and scope of the invention as defined in the following claims.

What is claimed is:

1. A method for fabricating semiconductor devices, comprising the steps of:
loading a plurality of substrates maintained in a boat into an inner tube, the inner tube being of a cylindrical shape having open upper and lower ends, and being disposed in an outer tube, the outer tube being of a cylindrical shape having a closed upper end and an open lower end;
supplying a processing gas into the inner tube to process the substrates; and
evacuating the processing gas through an exhaust path formed between the inner tube and the outer tube,
wherein a non-reactive gas is provided to an inner surface of the closed upper end of the outer tube during the step of supplying the processing gas.

2. The method of claim 1, wherein the processing gas is a TEOS and O₃ gas and is provided to form an oxide film on the substrates.

3. The method of claim 1, wherein the non-reactive gas is N₂.

4. The method of claim 1, wherein the non-reactive gas is an inert gas.

5. A method for fabricating semiconductor devices, comprising the steps of:
loading a plurality of substrates maintained in a boat into an inner tube, the inner tube being of a cylindrical shape having open upper and lower ends, and being disposed in an outer tube, the outer tube being of a cylindrical shape having a closed upper end and an open lower end;
supplying a processing gas into the inner tube to form a film on each of the substrates while the substrates are heated, wherein a non-reactive gas is provided to an inner surface of the closed upper end of the outer tube during the film forming process of the substrates; and
evacuating the processing gas through an exhaust path formed between the inner tube and the outer tube.

6. A semiconductor fabricating apparatus comprising:
an outer tube;
an inner tube disposed inside the outer tube, forming a substrate processing region;
a boat loaded into the substrate processing region while hosting a plurality of vertically stacked substrates;
a heater surrounding the outer tube for heating the substrates;
a gas supply line for providing a reaction gas from a bottom part of the inner tube; and
a non-reactive gas outlet provided in a part of the outer tube above the inner tube.

7. A semiconductor fabricating apparatus comprising:
an outer tube;
an inner tube disposed inside the outer tube, forming a substrate processing region;
a boat loaded into the substrate processing region while hosting a plurality of vertically stacked substrates;
a heater surrounding the outer tube for heating the substrates;
a gas supply line for providing a reaction gas from a bottom part of the inner tube; and
a non-reactive gas outlet facing toward an inner part of the outer tube above the inner tube.
